(19) United States
(12) Patent Application Publication
(10) Pub. No.: US 2007/0231714 A1
(43) Pub. Date: Oct. 4, 2007

(54) Photomask making method and semiconductor device manufacturing method

(75) Inventor: Takayoshi Minami, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/513,028

(22) Filed: Aug. 31, 2006

(30) Foreign Application Priority Data
Mar. 29, 2006 (JP) 2006-092045

(51) Int. Cl. G03C 5/00; G03F 1/00

(52) U.S. Cl. 430/5; 430/394

(57) ABSTRACT

A photomask making method and a semiconductor-device manufacturing method to improve the uniformity of the line widths of patterns. A gate electrode pattern and a gate wiring pattern are formed in a first photomask used in a double exposure process, and shift patterns are formed in a second photomask. Then, assist patterns are disposed at sides of the gate electrode pattern, and assist patterns are disposed at sides of the gate wiring pattern, in the first photomask. Inclusion patterns that include the assist patterns are disposed in the second photomask. With the double exposure process using the first photomask and the second photomask, the depth of focus obtained when the gate electrode pattern and the gate wiring pattern are exposed is improved, the uniformity of the line widths of the gate electrode pattern and the gate wiring pattern is increased.

### CROSS-REFERENCE TO RELATED APPLICATIONS

This application is based upon and claims the benefits of priority from the prior Japanese Patent Application No. 2006-092045, filed on Mar. 29, 2006, the entire contents of which are incorporated herein by reference.

### BACKGROUND OF THE INVENTION

1. Field of the Invention

The present invention relates to photomask making methods and semiconductor device manufacturing methods, and particularly, to a photomask making method using a double exposure process and a semiconductor device manufacturing method using a photomask made by the photomask making method.

2. Description of the Related Art

As semiconductor devices have been required to be manufactured in a more microscopic manner these days, a double exposure process has been introduced to form micro-patterns and micro-pitches. In this process, attention is paid to a phase edge technology. The phase edge technology is mainly used to form gate electrode patterns. Binary masks or half-tone phase shift masks are used to form micro-patterns, and Levenson phase shift masks are used to form further micro-patterns.

When a gate electrode pattern is formed using a Levenson phase shift mask, shifters (shift patterns) having phases of 0 degree and π (180) degrees are disposed at both sides of the gate electrode pattern. Since a shift pattern reverses the phases of adjacent aperture patterns by 180 degrees to each other, the contrasts between the gate electrode pattern and the shift patterns are improved. As a result, exposure with the use of the Levenson phase shift mask gives a sufficient depth of focus, allowing patterns having nodes of 100 nm or less to be made in a stable manner (for example, see the specifications of U.S. Pat. Nos. 5,573,890 and 5,858,580).

When a binary mask or a half-tone phase shift mask is used for exposure in the double exposure process, since the binary mask or the half-tone phase shift mask forms a pattern at about the resolution limit, a sufficient depth of focus (DOF) cannot be obtained. As a result, when a gate electrode pattern is formed using the binary mask or the half-tone phase shift mask, the uniformity of the line width of the gate electrode pattern cannot be obtained due to a focusing shift that occurs during exposure.

To solve this issue, an exposure process has been proposed in which the phase edge technology and assist patterns (scattering bars) are combined (in Japanese Patent Application No. 2004-568745).

In this exposure process, a gate electrode pattern and a gate wiring pattern are disposed in a first photomask. In addition, assist patterns having the resolution limit or more are disposed at sides of the gate electrode pattern, and assist patterns having the resolution limit or less are disposed at sides of the gate wiring pattern.

Shift patterns for the gate electrode pattern are disposed in a second photomask so as to include the assist patterns formed at the sides of the gate electrode pattern.

When double exposure is performed with these two photomasks, a micro gate electrode pattern and a gate wiring pattern are formed and assist patterns are formed at the sides thereof with exposure using the first photomask, and the gate electrode pattern is made thinner and the assist patterns formed at the sides of the gate electrode pattern are removed by the shift patterns with exposure using the second photomask.

According to such a process, since the assist patterns having the resolution limit or more are disposed at the sides of the gate electrode pattern on the first photomask, the depth of focus (DOF) obtained when the gate electrode pattern is exposed is improved, and the uniformity of the line width of the gate electrode pattern is increased. Since the assist patterns transferred are removed by the shift patterns of the second photomask, no assist pattern is left.

The relationship between the line width of assist patterns and the depth of focus, obtained when the assist patterns are disposed at sides of a gate electrode pattern will be described. FIG. 27 shows such a relationship. It is understood from FIG. 27 that the larger the line width of the assist patterns is, the better the depth of focus becomes. This is the reason why the assist patterns having the resolution limit or more are disposed at the sides of the gate electrode pattern in the above-described exposure process.

In the above exposure process, however, when the gate electrode pattern and the gate wiring pattern are exposed, since the depth of focus is small when defocusing the gate wiring pattern, the line width of the gate wiring pattern obtained after exposure varies, and a very-narrow gate wire has a high resistance. In this case, a successful device characteristics cannot be sufficiently obtained.

### SUMMARY OF THE INVENTION

In view of the foregoing, it is an object of the present invention to provide a method for making a photomask capable of forming micro-patterns uniformly in a stable manner. Another object of the present invention is to provide a method for manufacturing a semiconductor device having uniform micro-patterns.

To accomplish one of the above objects, according to the present invention, there is provided a photomask making method. This photomask making method includes the steps of making a first photomask having a first pattern and a second pattern; making a second photomask having shift patterns at both sides of the first pattern, each of the shift patterns overlapping with the first pattern; adding first assist patterns at areas corresponding to the shift patterns in the first photomask and second assist patterns at sides of the second pattern in the first photomask; and adding third patterns at areas that include the first assist patterns and the second assist patterns, in the second photomask.

To accomplish one of the above objects, according to the present invention, there is provided a semiconductor device manufacturing method. This semiconductor device manufacturing method includes the steps of transferring a first pattern and a second pattern to a resist and transferring first assist patterns and second assist patterns at sides of the first pattern and the second pattern, respectively; and transferring shift patterns at both sides of the transferred first pattern, each of the shift patterns overlapping with the first pattern, to remove the first assist patterns, and transferring third patterns that include areas where the second assist patterns are transferred, to remove the second assist patterns.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is an example flowchart of a photomask data generating process.

FIG. 2 is an example outline plan of a main section in a first photomask.

FIG. 3 is an example outline plan of a main section in a second photomask.

FIG. 4 is an example flowchart of double exposure.

FIG. 5 is an outline plan of a main section in a gate-electrode and gate-wiring pattern data generating process.

FIG. 6 is an outline plan of a main section in a shift pattern data generating process.

FIG. 7 is an outline plan of a main section in a assist pattern data generating process.

FIG. 8 is an outline plan of a main section in a inclusion pattern data generating process.

FIG. 9 is an outline plan of a main section in first drawing data.

FIG. 10 is an outline plan of a main section in second drawing data.

FIG. 11 is an example outline plan of a main section in a first photomask.

FIG. 12 is an example outline plan of a main section in a second photomask.

FIG. 13 is an outline plan of a main section in a first-photomask exposure process.

FIG. 14 is an outline plan of a main section in a second-photomask exposure process.

FIG. 15 is an outline plan of a main section in a gate-electrode and gate-wiring pattern data generating process.

FIG. 16 is an outline plan of a main section in a shift pattern data generating process.

FIG. 17 is an outline plan of a main section in a assist pattern data generating process.

FIG. 18 is an outline plan of a main section in a inclusion pattern data generating process.

FIG. 19 is an outline plan of a main section in first drawing data.

FIG. 20 is an outline plan of a main section in second drawing data.

FIG. 21 is an example outline plan of a main section in a first photomask.

FIG. 22 is an example outline plan of a main section in a second photomask.

FIG. 23 is an outline plan of a main section in a first-photomask exposure process.

FIG. 24 is an outline plan of a main section in a second-photomask exposure process.

FIG. 25 shows an example layout of assist patterns having the resolution limit or less.

FIG. 26 shows an example layout of assist patterns having the resolution limit or more.

FIG. 27 shows the relationship between the line width of assist patterns and the depth of focus.

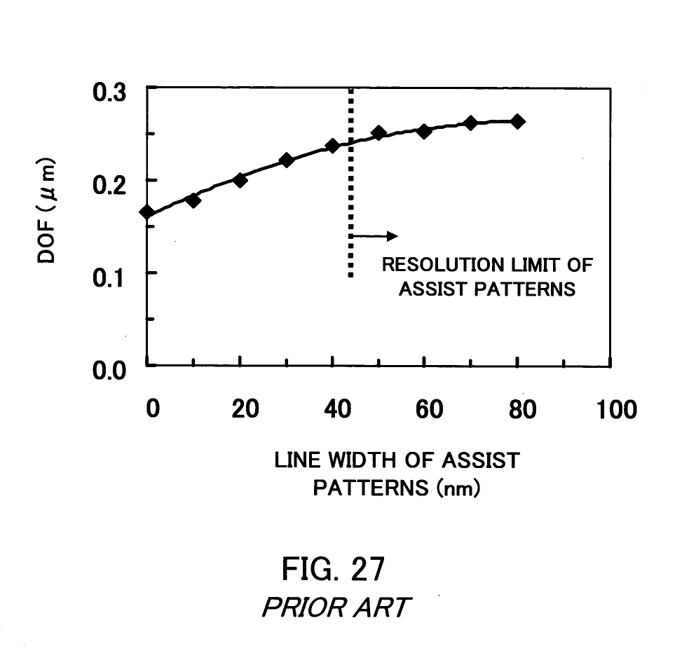

### DESCRIPTION OF THE PREFERRED EMBODIMENTS

Embodiments of the present invention will be described below by referring to the drawings.

First, the structures of photomasks used in a double exposure process will be described. In this process, two photomasks, a first photomask and a second photomask, are used.

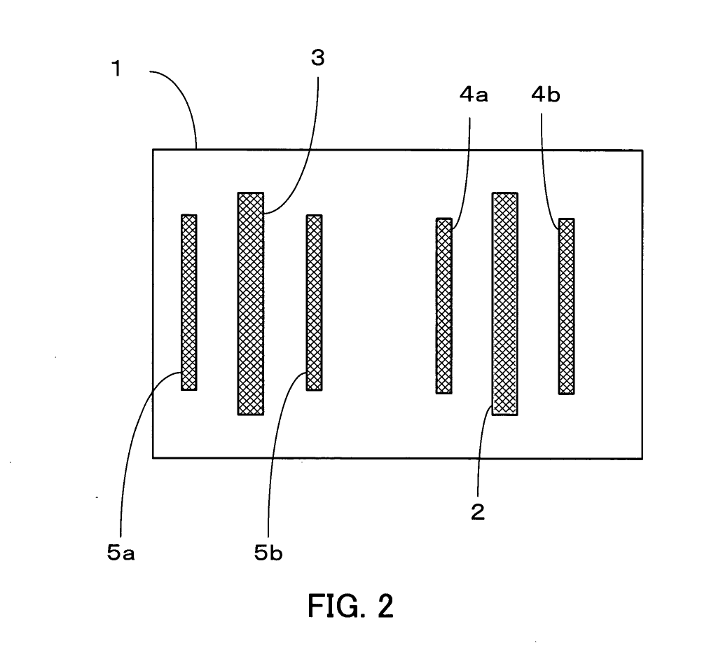

FIG. 2 shows an example outline plan of a main section of the first photomask 1. The first photomask 1 includes a gate electrode pattern 2, which is a first pattern, and a gate wiring pattern 3, which is a second pattern. In addition, first assist patterns 4a and 4b are disposed at sides of the gate electrode pattern 2, and second assist patterns 5a and 5b are disposed at sides of the gate wiring pattern 3.

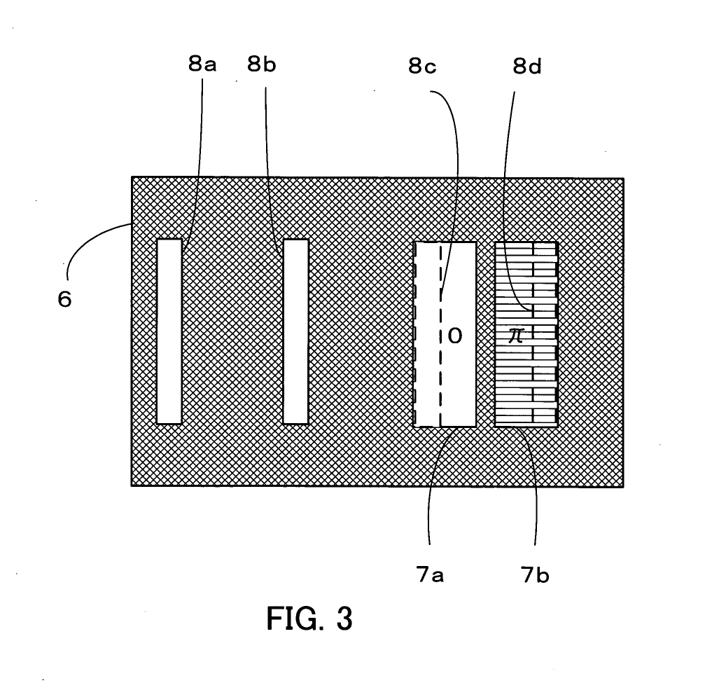

FIG. 3 shows an example outline plan of a main section of the second photomask 6. The second photomask 6 includes shift patterns 7a and 7b. In FIG. 3, “0” and “π” indicate the phases of optical oscillations, and for example, the shift pattern 7a has a phase of “0” and the shift pattern 7b has a phase of “π”. In the second photomask 6, inclusion patterns 8a, 8b, 8c, and 8d that include the second and first assist patterns 5a, 5b, 4a, and 4b, respectively, are also disposed as third patterns.

Next, a photomask-data generating process and an exposure process using a photomask made in the photomask-data generating process will be described.

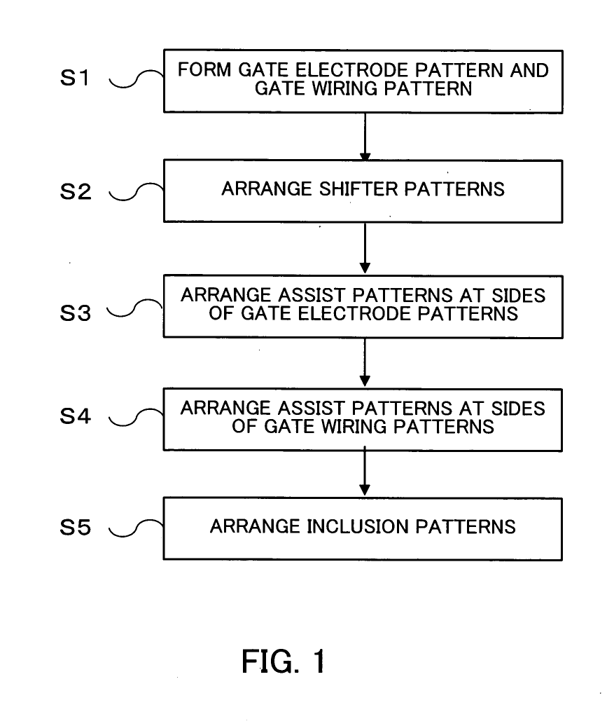

FIG. 1 is an example flowchart of the photomask-data generating process.

First, the gate electrode pattern and the gate wiring pattern are formed in the first photomask in step S1.

Then, the positions of the shift patterns are determined based on the position of the gate electrode pattern in the first photomask, and the shift patterns are disposed at the determined positions in the second photomask in step S2.

The first assist patterns are generated in the shift patterns formed in the second photomask, and are disposed at sides of the gate electrode pattern in the first photomask in step S3.

The second assist patterns are generated from the gate wiring pattern in the first photomask and are disposed at sides of the gate wiring pattern in the first photomask in step S4.

The inclusion patterns, which include the assist patterns disposed at the sides of the gate electrode pattern and the gate wiring pattern in the first photomask, are generated and disposed in the second photomask in step S5.

With this flow, in the first photomask, the gate electrode pattern and the gate wiring pattern are disposed, and the assist patterns are disposed at the sides of the gate electrode pattern and the gate wiring pattern; and in the second photomask, the shift patterns and the inclusion patterns are disposed.

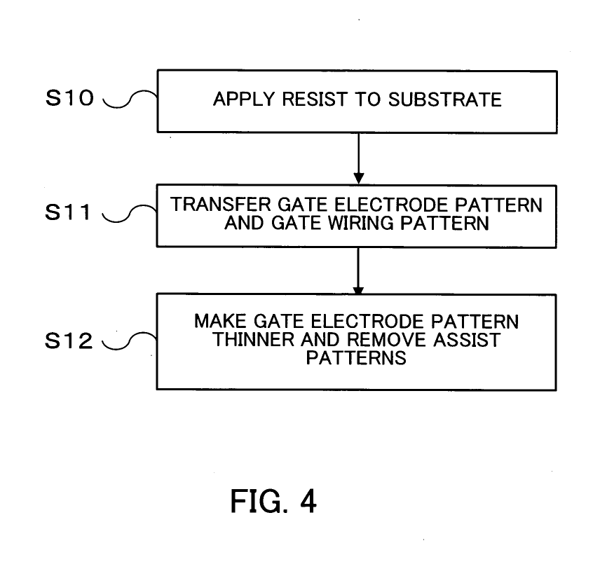

FIG. 4 is an example flowchart of double exposure.

In a resist double exposure process using the first photomask and the second photomask, after a resist is applied to a substrate in step S10, the gate electrode pattern and the gate wiring pattern are transferred, and the assist patterns are transferred at the sides of the gate electrode pattern and the gate wiring pattern with the first photomask in step S11.

Then, with the second photomask, the gate electrode pattern is made thinner, and the transferred assist patterns are removed in step S12.

When double exposure is applied to the resist with the use of the two photomasks in this way, exposure with the first photomask transfers the gate electrode pattern and the gate wiring pattern, and transfers the assist patterns at the sides thereof. Since the first photomask includes the assist patterns having the resolution limit or more at the sides of the gate electrode pattern and the gate wiring pattern, the depth of focus obtained when the gate electrode pattern and the gate wiring pattern are exposed is improved, and the uniformity, after exposure, of the line width of the gate electrode pattern and that of the gate wiring pattern is increased.

Exposure with the second photomask makes the line width of the gate electrode pattern smaller due to the shift patterns disposed in a gate electrode area. The inclusion patterns in the second photomask removes the assist patterns transferred at the sides of the gate electrode pattern and the gate wiring pattern.

The basic principle of a photomask making process will be described next by referring to figures.

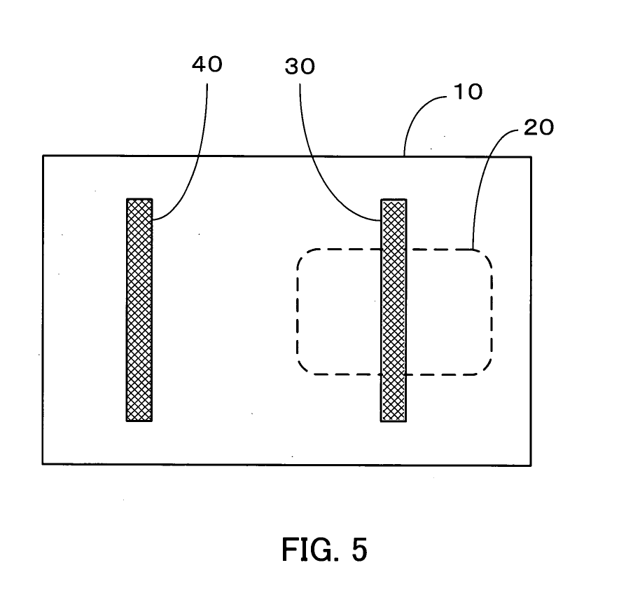

FIGS. 5 to 12 are example outline plans of main sections in the photomask making process.

FIG. 5 is an outline plan of a main section in a gate-electrode and gate-wiring pattern data generating process.

As shown in FIG. 5, a gate electrode pattern 30 to be formed on a chip area 20 is disposed in a photomask area 10. A gate wiring pattern 40 is also disposed. The gate electrode pattern 30 and the gate wiring pattern 40 serve as patterns in a first photomask.

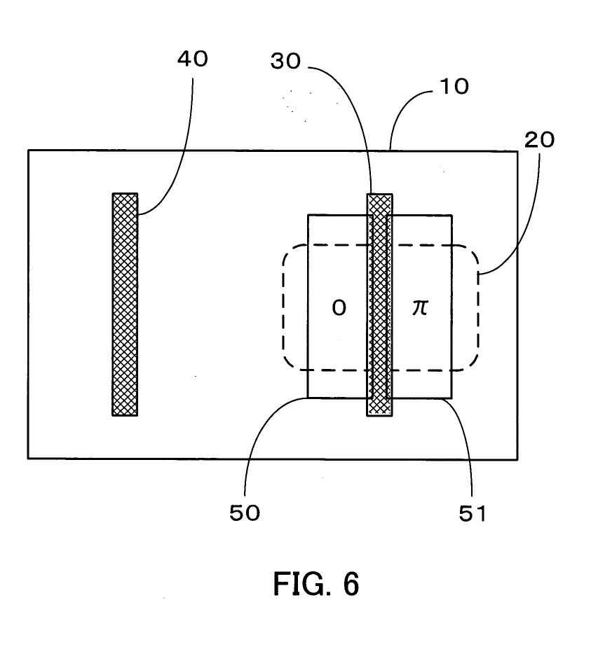

FIG. 6 is an outline plan of a main section in a shift pattern data generating process.

Shift patterns 50 and 51 are formed overlappingly with the gate electrode pattern 30. In FIG. 6, “0” and “π” indicate the phases of optical oscillations, and the shift pattern 50 has a phase of “0” and the shift pattern 51 has a phase of “π”. The shift patterns 50 and 51 serve as patterns in a second photomask.

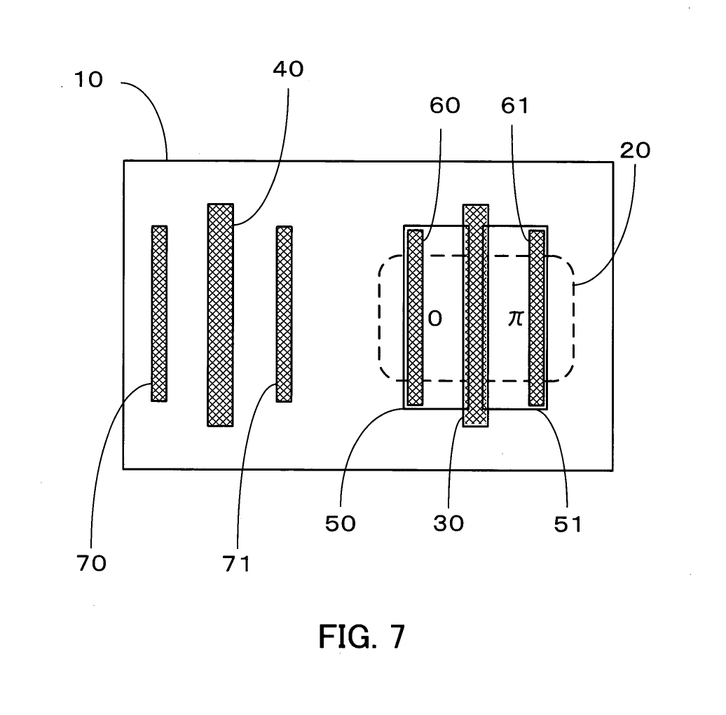

FIG. 7 is an outline plan of a main section in an assist pattern data generating process.

Assist patterns 60 and 61 are disposed at sides of the gate electrode pattern 30, and assist patterns 70 and 71 are disposed at sides of the gate wiring pattern 40. The assist patterns 60 and 61 are disposed in areas of the shift patterns 50 and 51 generated in FIG. 6. The assist patterns 60, 61, 70, and 71 serve as patterns in the first photomask.

The distances between the gate electrode pattern 30 and its assist patterns 60 and 61, and the distances between the gate wiring pattern 40 and its assist patterns 70 and 71 are made equal. This is to improve the depth of focus obtained when the gate electrode pattern 30 and the gate wiring pattern 60 are exposed.

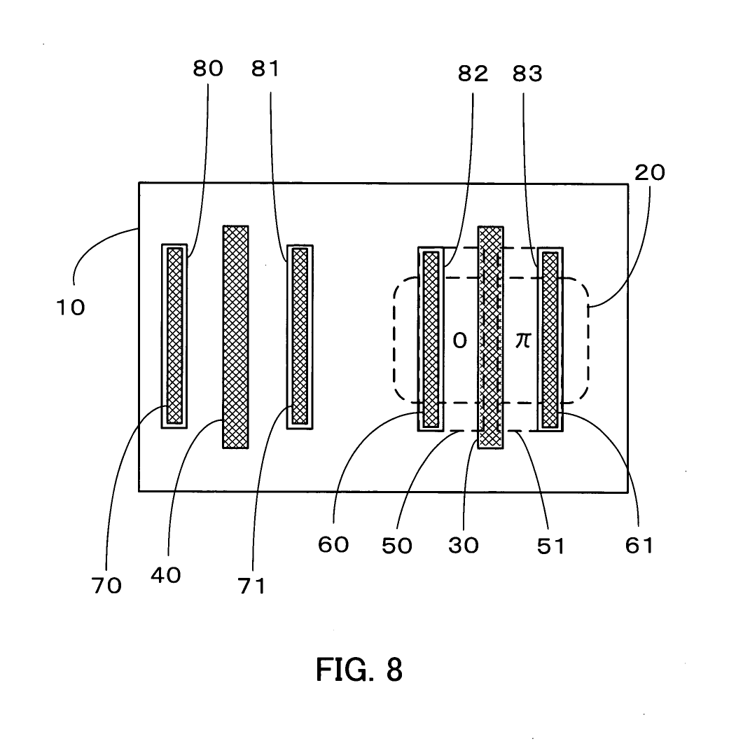

FIG. 8 is an outline plan of a main section in an inclusion pattern data generating process.

Patterns that can remove the assist patterns 60, 61, 70, and 71 formed in FIG. 7 in an exposure process, that is, inclusion patterns 80, 81, 82, and 83 that include the assist patterns 70, 71, 60, and 61, respectively, are formed. The inclusion patterns 80, 81, 82, and 83 serve as patterns in the second photomask.

In FIG. 8, the inclusion pattern 82 is disposed in the shift pattern 50 area, and the inclusion pattern 83 is disposed in the shift pattern 51 area, as an example case. When the inclusion patterns 82 and 83 are not disposed in the areas of the shift patterns 50 and 51, it is required that the inclusion pattern 82 and the shift pattern 50, and the inclusion pattern 83 and the shift pattern 51 be disposed with gaps provided therebetween. The reason for this requirement will be described below.

If the inclusion pattern 82 and the shift pattern 50, and the inclusion pattern 83 and the shift pattern 51 are not separated but disposed continuously, they overlap with each other.

When exposure light passing through the shift pattern 50 and exposure light passing through the inclusion pattern 82 have opposite phases, a chrome-less phase shift mask is generated at the overlapping portion. When exposure is performed with such a second photomask, exposure light is blocked at the overlapping portion, and an assist pattern transferred at the portion cannot be removed. Therefore, the inclusion pattern 82 and the shift pattern 50, and the inclusion pattern 83 and the shift pattern 51 should be separated at a predetermined distance and disposed.

A pattern-line-width correction process is then performed. The patterns are drawn to make the first photomask and the second photomask.

First drawing data and second drawing data are required to make the second photomask. This is because the first drawing data is used to form transparent areas of exposure light and the second drawing data is used to form a shifter only.

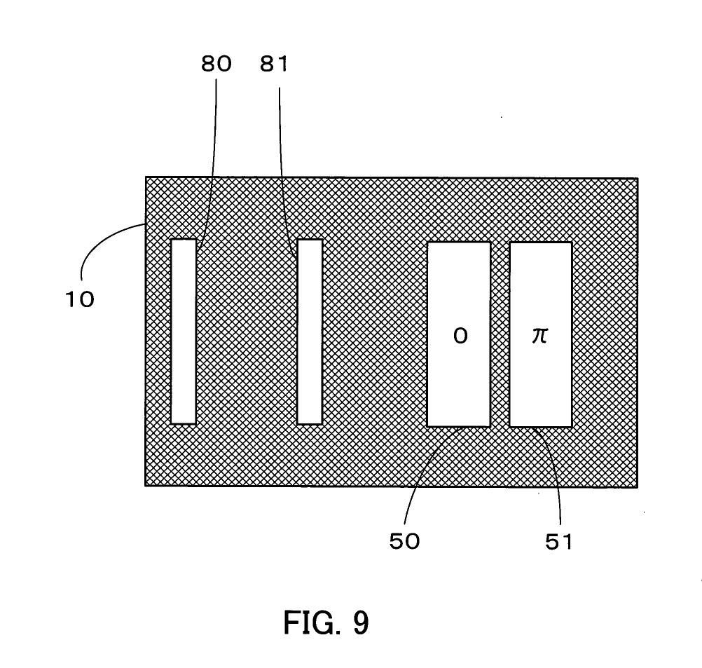

FIG. 9 is an outline plan of a main section in the first drawing data. The inclusion patterns 80 and 81 and the shift patterns 50 and 51 form the first drawing data. In first drawing, only the transparent areas of exposure light are formed. Therefore, the inclusion pattern data is drawn as data having the same phase.

Since the inclusion patterns 82 and 83, shown in FIG. 8, are disposed in the areas of the shift patterns 50 and 51, the inclusion patterns 82 and 83 are omitted in FIG. 9.

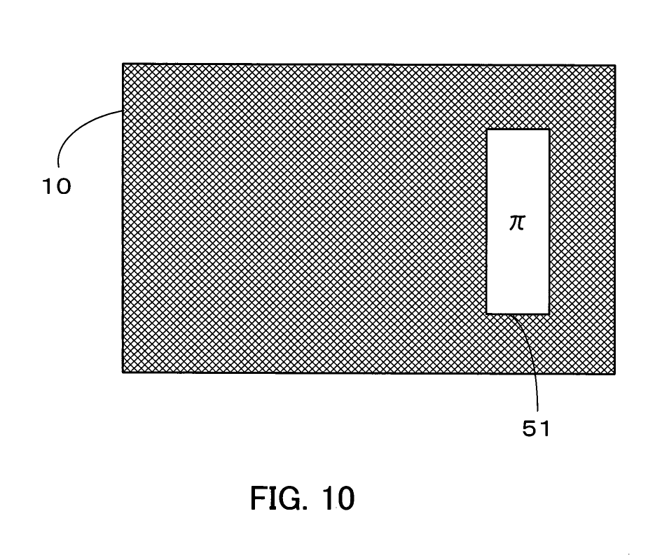

FIG. 10 is an outline plan of a main section in the second drawing data. The second drawing data is used to form the shifter only. For example, only the shift pattern 51 (having a phase of “π”) is drawn.

These two pieces of drawing data form the second photomask.

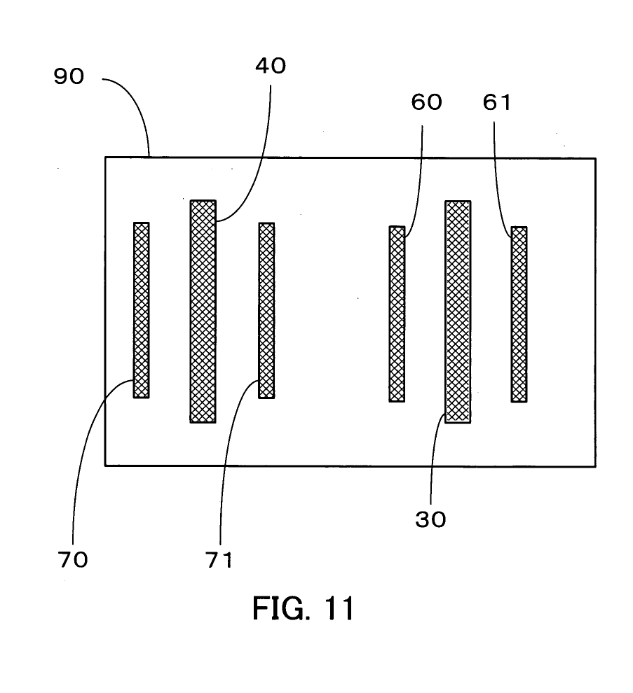

FIG. 11 is an example outline plan of a main section in a first photomask 90. The first photomask 90 includes the gate electrode pattern 30, the gate wiring pattern 40, and the assist patterns 60, 61, 70, and 71.

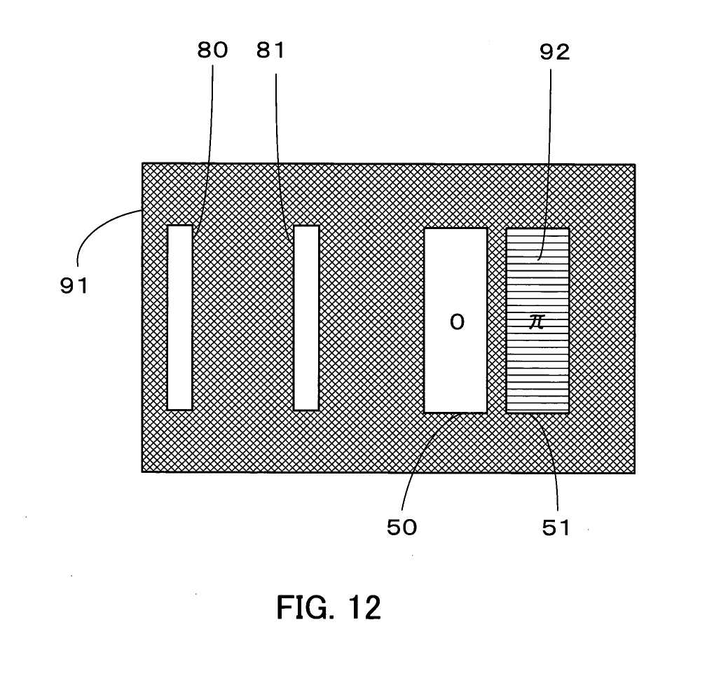

FIG. 12 is an example outline plan of a main section in a second photomask 91. The second photomask 91 includes the shift patterns 50 and 51 and the inclusion patterns 80 and 81. The shift pattern 51 form a shifter 92 having a phase of “π”.

With the use of the first photomask 90 and the second photomask 91 made by the above processes, a process for transferring the gate electrode pattern and the gate wiring pattern in double exposure will be described.

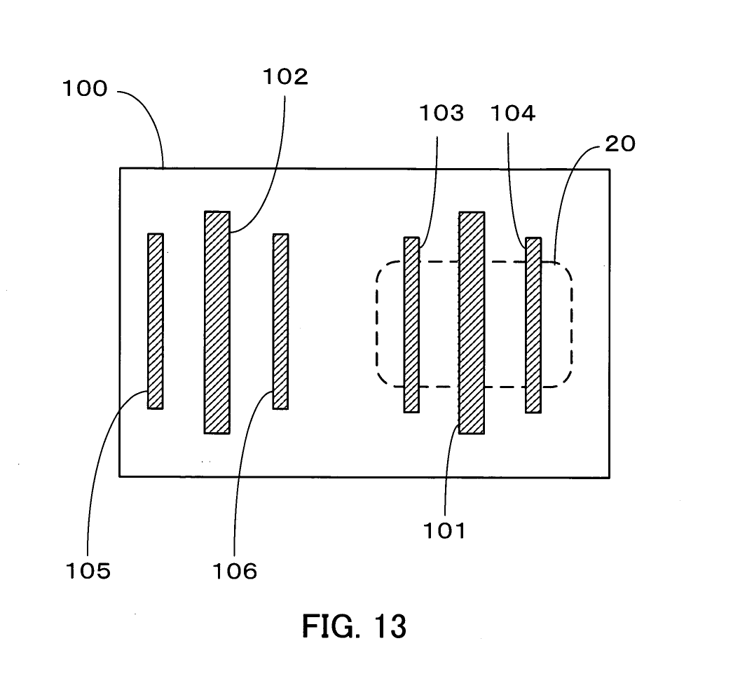

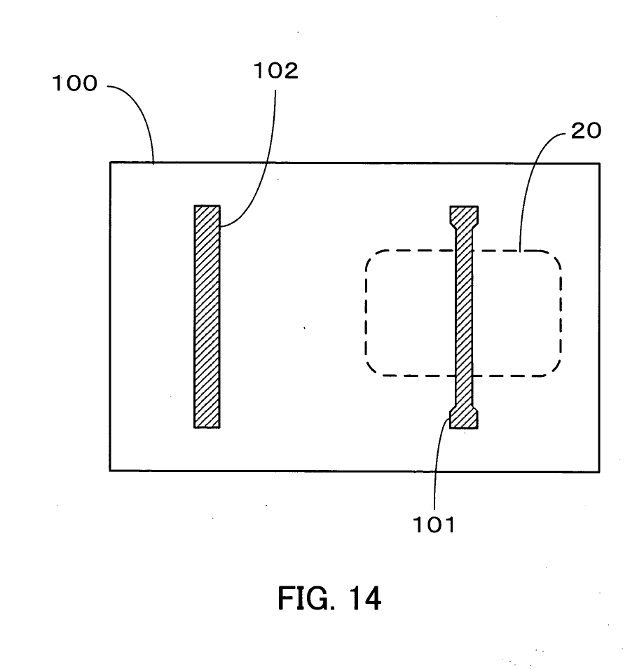

FIGS. 13 and 14 are example outline plans of main sections in a process for transferring the gate electrode pattern and the gate wiring pattern after a positive resist is applied to a substrate 100.

FIG. 13 is an outline plan of a main section in a first-photomask exposure process.

With exposure using the first photomask 90, shown in FIG. 11, a gate electrode pattern 101 is formed in the chip area 20 on the substrate 100, and a gate wiring pattern 102 is also formed. Assist patterns 103, 104, 105, and 106 are also formed at sides of the gate electrode pattern 101 and the gate wiring pattern 102.

FIG. 14 is an outline plan of a main section in a second-photomask exposure process.

With exposure using the second photomask 91, shown in FIG. 12, the gate electrode pattern 101 is made thinner. Since the shift patterns 50 and 51, which include the assist patterns 103 and 104, respectively, and the inclusion patterns 80 and 81, which includes the assist patterns 105 and 106, respectively, have been formed in the second photomask 91, the assist patterns 103, 104, 105, and 106 transferred on the substrate 100 are removed after exposure is performed using the second photomask 91.

In the above described double exposure process, the order of exposures with the first photomask 90 and the second photomask 91 can be reversed and the same result is obtained.

A specific example of the photomask making process will be described next by referring to figures.

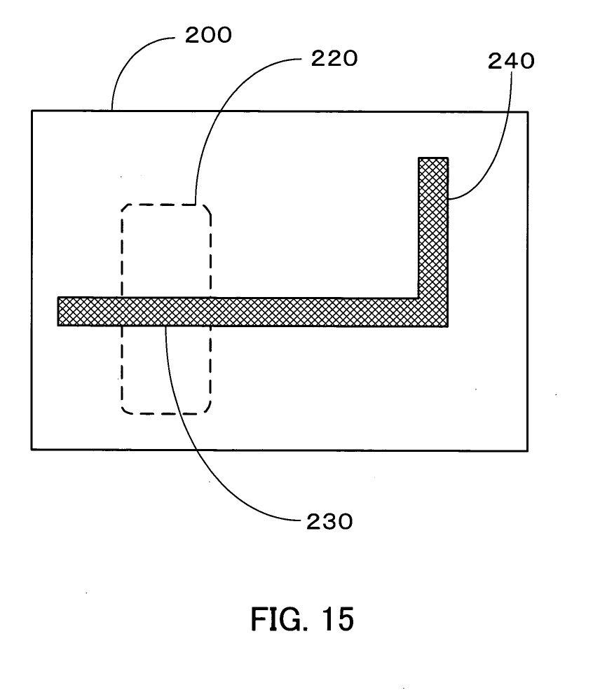

FIGS. 15 to 22 are example outline plans of main sections in the photomask making process.

FIG. 15 is an outline plan of a main section in a gate-electrode and gate-wiring pattern data generating process.

As shown in FIG. 15, a gate electrode pattern 230 to be formed on a chip area 220 is disposed in a photomask area 200. A gate wiring pattern 240 is also disposed. In this figure, the gate electrode pattern 230 and the gate wiring pattern 240 are connected at an angle of 90 degrees and disposed, as an example case. The gate electrode pattern 230 and the gate wiring pattern 240 serve as patterns in a first photomask.

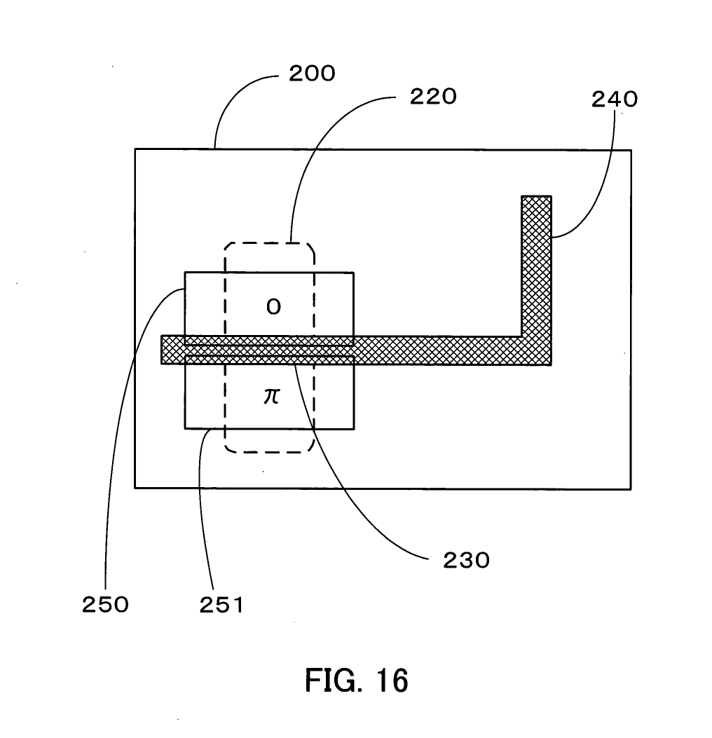

FIG. 16 is an outline plan of a main section in a shift pattern data generating process.

Shift patterns 250 and 251 are formed overlappingly with the gate electrode pattern 230. In FIG. 16, “0” and “π” indicate the phases of optical oscillations, and the shift pattern 250 has a phase of “0” and the shift pattern 251 has a phase of “π”. The shift patterns 250 and 251 serve as patterns in a second photomask.

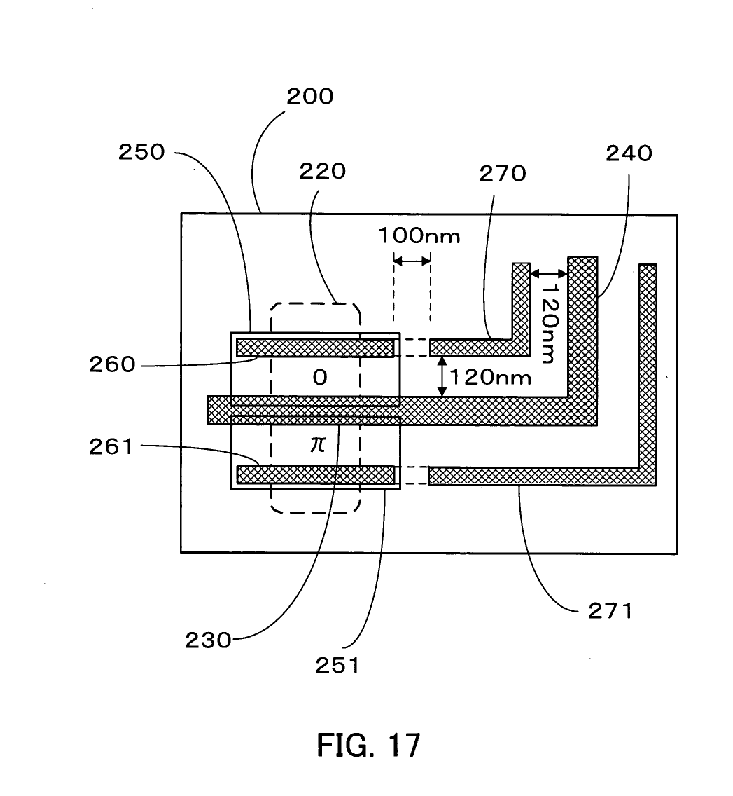

FIG. 17 is an outline plan of a main section in an assist pattern data generating process.

Assist patterns 260 and 261 are disposed at sides of the gate electrode pattern 230, and assist patterns 270 and 271 are disposed at sides of the gate wiring pattern 240. The assist patterns 260 and 261 are disposed in areas of the shift patterns 250 and 251 generated in FIG. 16.

In this figure, the distances between the gate electrode pattern 230 and the assist patterns 260 and 261, and the distances between the gate wiring pattern 240 and the assist patterns 270 and 271 are set to 120 nm as an example case. If the distances are smaller than this value, a mask error enhancement factor (MEEF) becomes large. Therefore, when the gate electrode pattern 230 and the gate wiring pattern 240 are formed as resist patterns, line edge roughness (LER) becomes large. If the distances are larger than this value, the depth of focus becomes small.

The line width of the assist patterns 260, 261, 270, and 271 is set, for example, to 60 nm (resolution=0.26×λ/NA, where the wavelength λ of exposure light is 193 nm and the numerical aperture NA of a projection lens is 0.85). When a space is limited, the line width can be reduced in a step wise to 40 nm (resolution=0.18×λ/NA, where the wavelength λ of exposure light is 193 nm and the numerical aperture NA of a projection lens is 0.85).

The line width of the assist patterns 260, 261, 270, and 271 is appropriately changed in this way based on the line width and pitch of the gate electrode pattern 230 and the gate wiring pattern 240.

The distance between the assist patterns 260 and 270 and the distance between the assist patterns 261 and 271 are set, for example, to 100 nm. They need to be separated for the reason described later.

The assist patterns 260, 261, 270, and 271 serve as patterns in the first photomask.

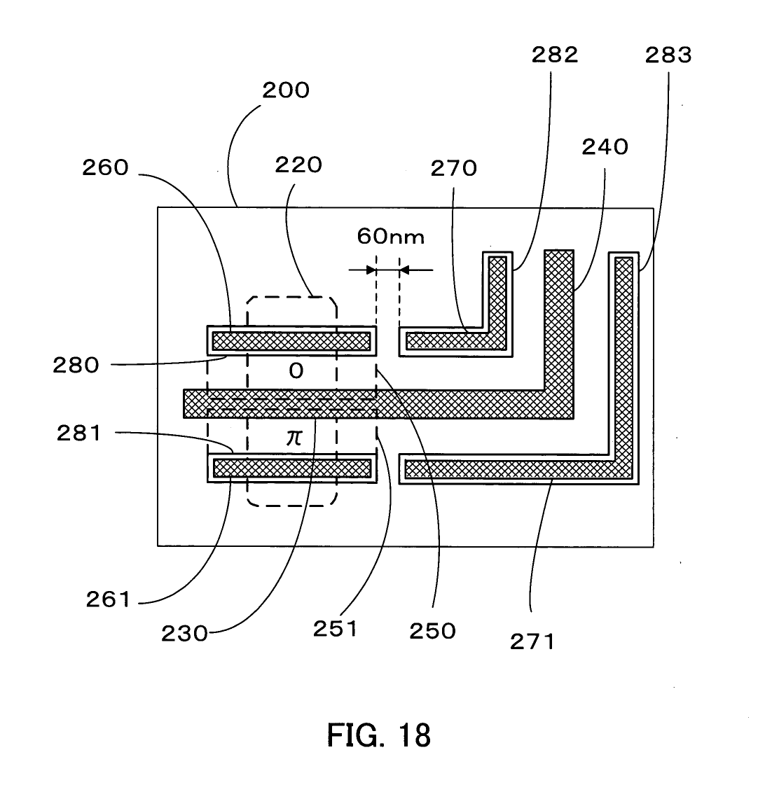

FIG. 18 is an outline plan of a main section in an inclusion pattern data generating process.

Patterns that can remove the assist patterns 260, 261, 270, and 271 formed in FIG. 17 in an exposure process, that is, inclusion patterns 280, 281, 282, and 283 that include the assist patterns 260, 261, 270, and 271, respectively, are formed.

The line width of the inclusion patterns 280, 281, 282, and 283 is, for example, 20 nm wider at both sides than the assist patterns 260, 261, 270, and 271.

Since the line width of the assist patterns is 60 nm in the above description, the line width of the inclusion patterns is 100 nm. When the line width of the assist patterns is set to 40 nm, the line width of the inclusion patterns is 80 nm.

Since the distance between the assist patterns 260 and 270 and the distance between the assist patterns 261 and 271 are 100 nm as shown in FIG. 17, the distance between the inclusion patterns 280 and 282 and the distance between the inclusion patterns 281 and 283 are 60 nm.

The reason why the assist patterns 260 and 270 and the assist patterns 261 and 271 are disposed separately with each other, described by referring to FIG. 17, will be explained here.

If the assist patterns 260 and 270 and the assist patterns 261 and 271 are disposed not separately but continuously, the shift pattern 250 and the inclusion pattern 282, and the shift pattern 251 and the inclusion pattern 283 overlap with each other.

In that case, when exposure light passing through the shift pattern 250 and exposure light passing through the inclusion pattern 282 have opposite phases, for example, a chrome-less phase -shift mask is formed at the overlapping portion. Therefore, when exposure is performed with the second photomask, exposure light is blocked at the overlapping portion, and the assist pattern transferred at the overlapping portion cannot be removed. To overcome this problem, the assist patterns 260 and 270 and the assist patterns 261 and 271 are separated and disposed.

The inclusion patterns 280, 281, 282, and 283 serve as patterns in the second photomask.

In FIG. 18, the inclusion pattern 280 is disposed in the shift pattern 250, and the inclusion pattern 281 is disposed in the shift pattern 251, as an example case. When the inclusion patterns 280 and 281 are not disposed in the shift patterns 250 and 251, respectively, the inclusion pattern 280 and the shift pattern 250, and the inclusion pattern 281 and the shift pattern 251 should be disposed with a distance (for example, 60 nm) provided therebetween. Since the reason of these separation is the same as that described above, a description thereof is omitted here.

Then, pattern-line-width correction processing is performed. Specifically, optical-proximity-effect correction processing is performed.

The patterns are drawn to make the first photomask and the second photomask.

To make the second photomask, first drawing data and second drawing data are necessary, as described above.

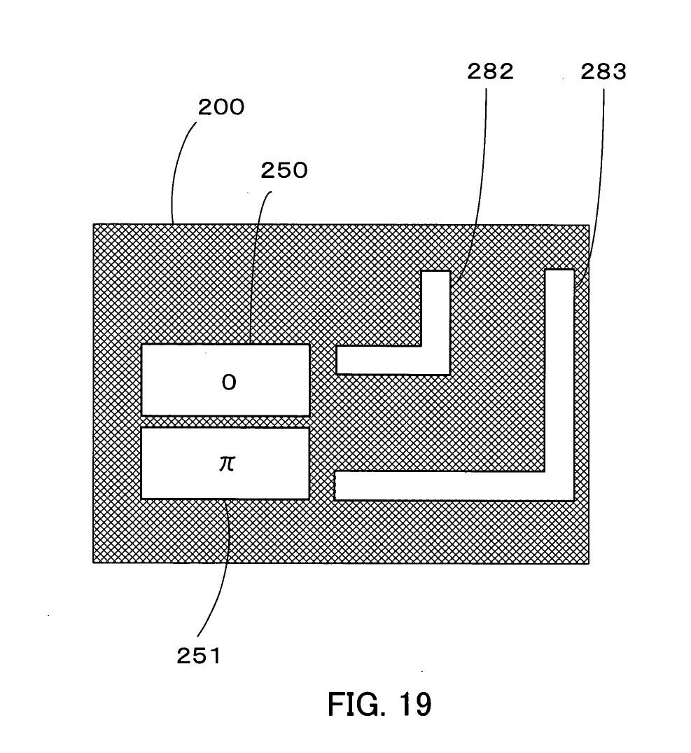

FIG. 19 is an outline plan of a main section in the first drawing data. The inclusion patterns 282 and 283 and the shift patterns 250 and 251 form the first drawing data. In first drawing, only the transparent areas of exposure light are formed. Therefore, the inclusion pattern data is drawn as data having the same phase.

Since the inclusion patterns 280 and 281, shown in FIG. 18, are disposed in the areas of the shift patterns 250 and 251, the inclusion patterns 280 and 281 are omitted in FIG. 19.

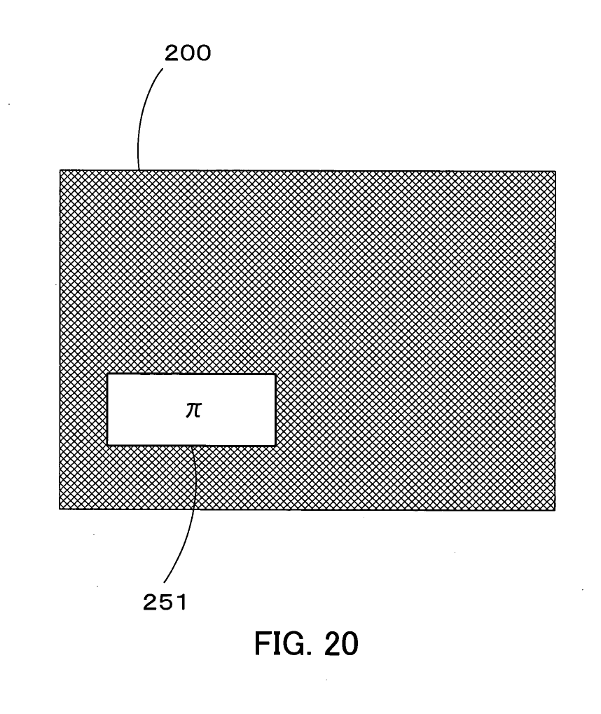

FIG. 20 is an outline plan of a main section in the second drawing data. The second drawing data is used to form a shifter only. For example, only the shift pattern 251 (having a phase of “π”) is drawn.

These two pieces of drawing data form the second photomask.

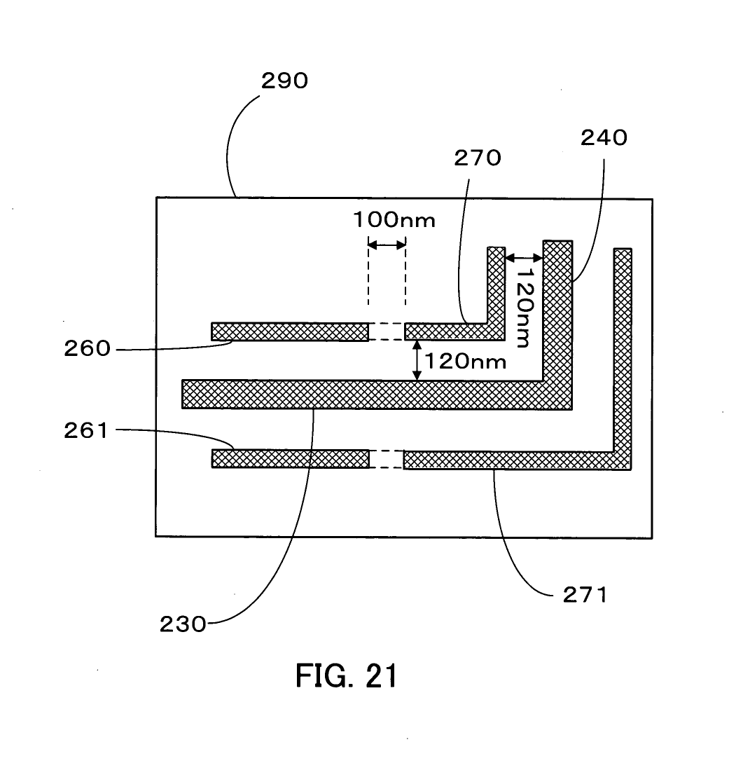

FIG. 21 is an example outline plan of a main section in a first photomask 290. The first photomask 290 includes the gate electrode pattern 230, the gate wiring pattern 240, and the assist patterns 260, 261, 270, and 271. The first photomask 290 is used, for example, as a half-tone phase shift mask for an ArF excimer laser.

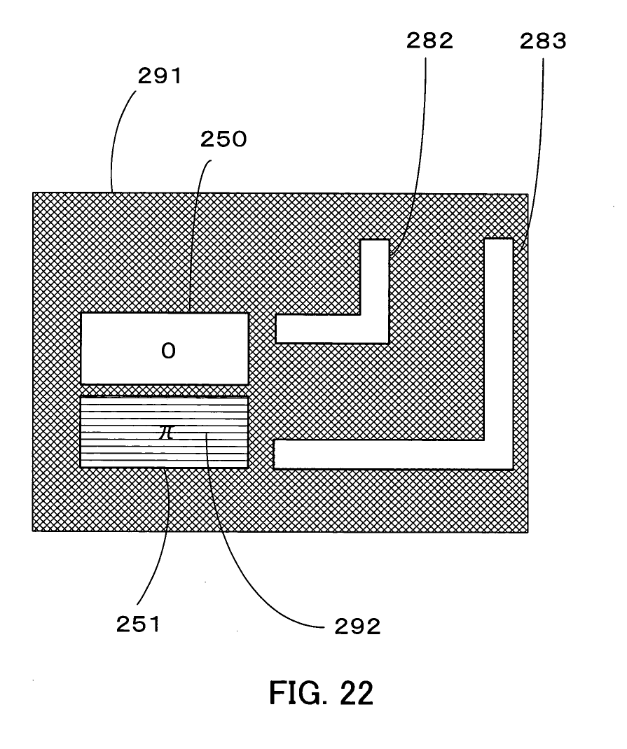

FIG. 22 is an example outline plan of a main section in a second photomask 291. The second photomask 291 includes the shift patterns 250 and 251 and the inclusion patterns 282 and 283. The shift pattern 251 form a shifter 292 having a phase of “π”. The second photomask 291 is used, for example, as a Levenson phase shift mask for an ArF excimer laser.

With the use of the first photomask 290 and the second photomask 291 made by the above processes, a process for transferring the gate electrode pattern and the gate wiring pattern in double exposure will be described.

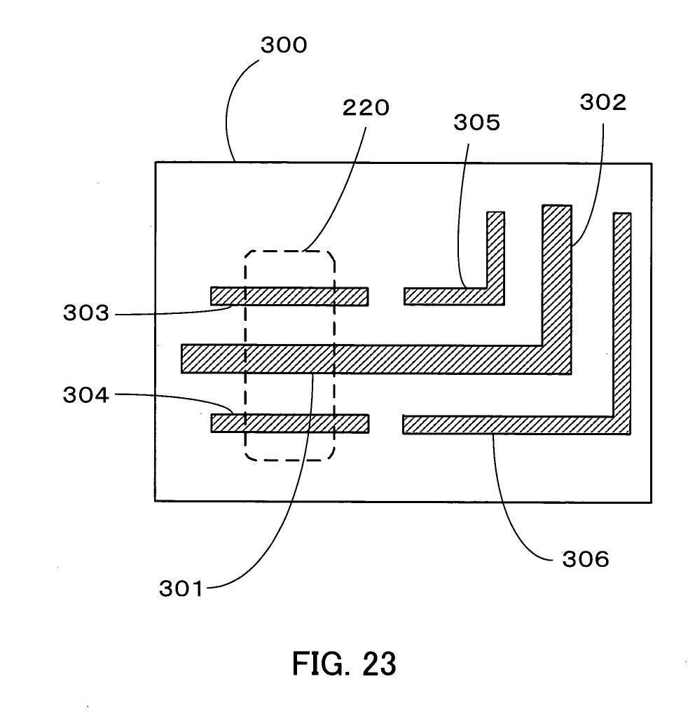

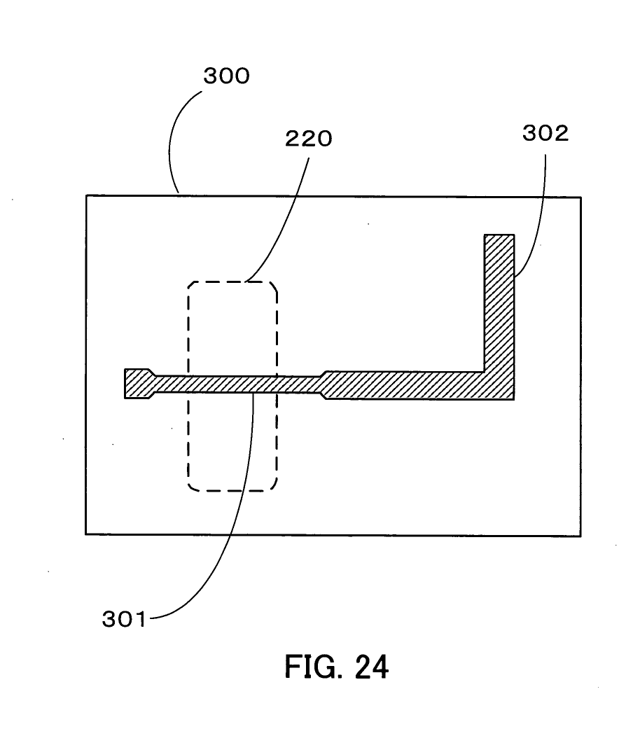

FIGS. 23 and 24 are example outline plans of main sections in a process for transferring the gate electrode pattern and the gate wiring pattern to a positive resist applied to a substrate 300.

FIG. 23 is an outline plan of a main section in a first-photomask exposure process.

On a wafer substrate on which the chip area 220 is formed, SiO₂ (1 nm) serving as a gate oxide film, for example, is formed, and then, a poly-Si film having a thickness of about 100 nm is formed (not shown). An organic reflection-prevention film (about 80 nm) is applied thereto (not shown). Then, an ArF positive resist serving as a photosensitive material is applied with a thickness of about 250 to 300 nm (not shown).

The substrate 300, to which the positive resist has been applied, is exposed to light using the first photomask 290, shown in FIG. 21, by a reduction projection exposure apparatus having an ArF excimer laser as a light source to form a gate electrode pattern 301 in the chip area 220 on the substrate 300, and a gate wiring pattern 302.

The exposure conditions are set, for example, as follows:

NA=0.85, ⅔ annular illumination is used (σ=0.567 or 0.85), and amount of exposure=150 to 200 J/m².

Assist patterns 303, 304, 305, and 306 are also formed at sides of the gate electrode pattern 301 and the gate wiring pattern 302. The line width of the assist patterns 303, 304, 305, and 306 is about 60 nm.

FIG. 24 is an outline plan of a main section in a second-photomask exposure process.

The exposure conditions are set, for example, as follows:

NA=0.85, σ=0.30, and amount of exposure=80 to 120 J/m².

Then, thermal treatment (post exposure bake: PEB) and developing are performed to form resist patterns.

With exposure using the shift patterns 250 and 251 in the second photomask 291, shown in FIG. 22, the gate electrode pattern 301 is made thinner.

Since the shift patterns 250 and 251, which include the assist pattern 303 and 304, respectively, and the inclusion patterns 282 and 283, which include the assist patterns 305 and 306, respectively, are formed in the second photomask, the assist patterns 303, 304, 305, and 306 formed on the substrate 300 are removed after exposure is performed using the second photomask.

Since the assist patterns 260, 261, 270, and 271 having the resolution limit or more are disposed at sides of the gate electrode pattern 230 and the gate wiring pattern 240 in the first photomask 290, as shown in FIG. 21, the depth of focus obtained when the gate electrode pattern 301 and the gate wiring pattern 302 are formed is improved, and the uniformity of the line widths of the gate electrode pattern 301 and the gate wiring pattern 302 is increased.

Since the shift patterns 250 and 251 are disposed in the second photomask, as shown in FIG. 22, the gate electrode pattern 301 is made thinner after exposure.

The assist patterns 303 and 304 are removed by the shift patterns 250 and 251, which includes the assist patterns 303 and 304, and the assist patterns 305 and 306 are removed by the inclusion patterns 282 and 283.

In the above described double exposure process, the order of exposures with the first photomask 290 and the second photomask 291 can be reversed and the same result is obtained.

When an exposure process in which assist patterns are removed by a second photomask is used as in the present invention, the layout margins of the assist patterns are increased.

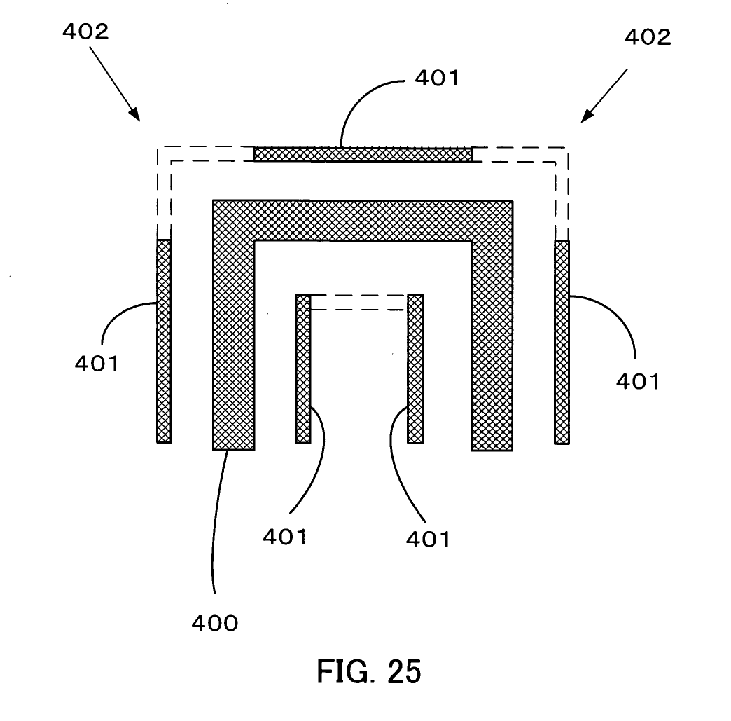

FIG. 25 shows an example layout of assist patterns having a line width of the resolution limit or less.

When a gate wiring pattern 400 has crossing portions 402 in a first photomask, for example, an assist pattern 401 having a line width of the resolution limit or less cannot be disposed at sides thereof. This is because, when the assist pattern 401 has crossing portions, even if the line width is equal to or less than the resolution limit, the assist pattern 401 is likely to be transferred to a resist at the crossing portions 402. Therefore, when the assist pattern 401 is not removed by a double exposure process, it is necessary to make the assist pattern 401 discontinuously at the crossing portions in the first photomask, as shown in FIG. 25.

As in the present invention, when an exposure process is used in which assist patterns having a line width of the resolution limit or more are transferred and then the assist patterns are removed by a second photomask, an assist pattern can be continuously disposed at sides of a crossing portion of wiring.

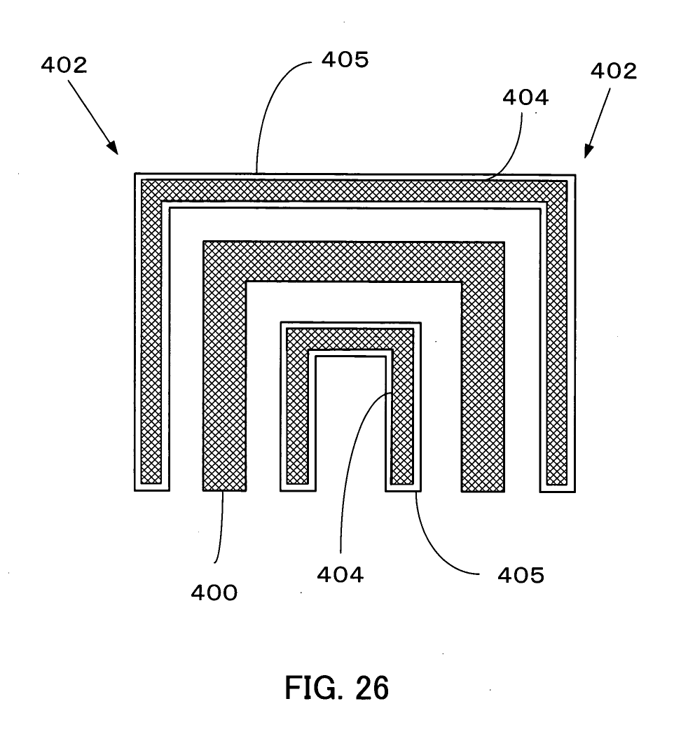

FIG. 26 is an example layout of assist patterns having a line width of the resolution limit or more.

As shown in FIG. 26, when assist patterns 404 having a line width of the resolution limit or more are used, the assist patterns 404 can be continuously disposed at sides of crossing portions 402. When a first photomask has the assist patterns 404 and a second photomask has inclusion patterns 405 that include the assist patterns 404, the transferred assist patterns 404 are removed by the second photomask.

As described above, according to the present invention, the layout margins of assist patterns are also increased. Since a process for making photomasks of the patterns shown in FIG. 26 is the same as that described above, a description thereof is omitted here.

In the present invention, a first photomask includes a first pattern and a second pattern, and first assist patterns and second assist patterns at sides thereof, and a second photomask includes shift patterns and third patterns. When exposures are performed with the first photomask and the second photomask in that order, the first assist patterns, the second assist patterns, and the shift patterns make the first pattern and the second pattern uniform and thinner; and the transferred first assist patterns and second assist patterns of the first photomask are removed by the third patterns, which include the transfer areas thereof, of the second photomask.

With such an exposure process, a semiconductor device having uniform thin patterns is implemented.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A photomask making process comprising the steps of:
making a first photomask having a first pattern and a second pattern;
making a second photomask having shift patterns at both sides of the first pattern, each of the shift patterns overlapping with the first pattern;
adding first assist patterns at areas corresponding to the shift patterns in the first photomask and second assist patterns at sides of the second pattern in the first photomask; and
adding third patterns at areas that include the first assist patterns and the second assist patterns, in the second photomask.

2. The photomask making process according to claim 1, wherein, in the step of adding the first assist patterns at the areas corresponding to the shift patterns in the first photomask and the second assist patterns at sides of the second pattern in the first photomask, the line width of the first assist patterns and the second assist patterns is equal to or more than the resolution limit when the first assist patterns and the second assist patterns are transferred to a resist.

3. The photomask making process according to claim 1, wherein, in the step of adding the third patterns at the areas that include the first assist patterns and the second assist patterns, in the second photomask, the third patterns form first drawing data for the second photomask.

4. The photomask making process according to claim 1, wherein, in the step of making the second photomask having the shift patterns at both sides of the first pattern, each of the shift patterns overlapping with the first pattern, a part of the shift patterns form second drawing data for the second photomask.

5. The photomask making process according to claim 1, wherein, in the step of adding the third patterns at the areas that include the first assist patterns and the second assist patterns, in the second photomask, the third patterns which include the first assist patterns are included in the shift patterns.

6. The photomask making process according to claim 1, wherein, in the step of adding the third patterns at the areas that include the first assist patterns and the second assist patterns, in the second photomask, the third patterns which include the first assist patterns are disposed at a predetermined distance from the shift patterns.

7. The photomask making process according to claim 2, wherein the line width of the first assist patterns and the second assist patterns is variable according to the line widths and pitch of the first pattern and the second pattern.

8. A semiconductor-device manufacturing method comprising the steps of:
transferring a first pattern and a second pattern to a resist and transferring first assist patterns and second assist patterns at sides of the first pattern and the second pattern, respectively; and
transferring shift patterns at both sides of the transferred first pattern, each of the shift patterns overlapping with the first pattern, to remove the first assist patterns, and transferring third patterns that include areas where the second assist patterns are transferred, to remove the second assist patterns.

9. The semiconductor-device manufacturing method according to claim 8, wherein, in the step of transferring the first pattern and the second pattern to the resist and transferring the first assist patterns and the second assist patterns at sides of the first pattern and the second pattern, respectively, the line width of the first assist patterns and the second assist patterns is equal to or more than a resolution limit when the first assist patterns and the second assist patterns are transferred to the resist.

10. The semiconductor-device manufacturing method according to claim 9, wherein the line width of the first assist patterns and the second assist patterns is variable according to the line widths and pitch of the first pattern and the second pattern.
